(19) United States
(12) Patent Application Publication
(10) Pub. No.: US 2026/0089874 A1
(43) Pub. Date: Mar. 26, 2026

(54) FAN CONTROL FOR HEADSET COMPUTING DEVICE

(71) Applicant: Apple Inc., Cupertino, CA (US)

(72) Inventors: Kartik R. Venkatraman, San Francisco, CA (US); Archana Venkatesh, Santa Clara, CA (US); Prateek Malhotra, San Francisco, CA (US)

(73) Assignee: Apple Inc., Cupertino, CA (US)

(21) Appl. No.: 18/895,988

(22) Filed: Sep. 25, 2024

(51) Int. Cl. H05K 7/20; G06F 1/16; G06F 1/20

(52) U.S. Cl. CPC H05K 7/20209; G06F 1/163; G06F 1/203; H05K 7/20972

(57) ABSTRACT

Circuits, methods, and apparatus that can control components of headset computing devices and other devices. An example can determine whether a headset computing device is being worn. If the headset computing device is not being worn, a fan can be stopped. If the headset computing device is being worn, a determination can be made as to whether a temperature of the headset computing device is above a first temperature. If it is, the fan can be turned on. If the temperature of the headset computing device is below the first temperature, the fan can be turned off.

### BACKGROUND

The number of types of electronic devices that are commercially available has increased tremendously the past few years and the rate of introduction of new electronic devices shows no signs of abating. Electronic devices such as tablet computers, laptop computers, all-in-one computers, desktop computers, smart phones, storage devices, wearable-computing devices, portable media players, portable computing devices, navigation systems, monitors, audio devices, remotes, adapters, and others have become ubiquitous.

Wearable computing devices in the form of headset computing devices are becoming very popular and many people are engaging with them for the first time. These headset computing devices can be designed to operate in various ways. Thus what is needed are circuits, methods, and apparatus that can control components of headset computing devices during operation.

### SUMMARY

Embodiments of the present invention can provide circuits, methods, and apparatus that can control components of headset computing devices. An illustrative embodiment of the present invention can determine whether a headset computing device is being worn. If it is not being worn, a fan can be stopped. If the headset computing device is being worn, a determination can be made as to whether a temperature of the headset computing device is above a first temperature. If it is, the fan can be turned on. If the temperature of the headset computing device is below the first temperature, the fan can be turned off.

Various embodiments of the present invention can incorporate one or more of these and the other features described herein. A better understanding of the nature and advantages of the present invention can be gained by reference to the following detailed description and the accompanying drawings.

### BRIEF DESCRIPTION OF THE DRAWINGS

FIG. 1 is a block diagram of a headset computing device according to an embodiment of the present invention;

FIG. 2 is a block diagram of a system for controlling a fan according to an embodiment of the present invention;

FIG. 3 illustrates a method of operating a fan of a headset computing device according to an embodiment of the present invention;

FIG. 4 illustrates another method of operating a fan of a headset computing device according to an embodiment of the present invention;

FIG. 5 illustrates another method of operating a fan of a headset computing device according to an embodiment of the present invention;

FIG. 6 illustrates another method of operating a fan of a headset computing device according to an embodiment of the present invention;

FIG. 7 illustrates a method of operating a fan of a headset computing device using more than one temperature threshold according to an embodiment of the present invention;

FIG. 8 illustrates a method of operating multiple fans of a headset computing device according to an embodiment of the present invention;

FIG. 9 illustrates another method of operating a fan of a headset computing device according to an embodiment of the present invention;

FIG. 10 illustrates another method of operating a fan of a headset computing device according to an embodiment of the present invention;

FIG. 11 illustrates a method of operating a fan of a headset computing device using more than one temperature threshold according to an embodiment of the present invention; and

FIG. 12 illustrates a method of operating a headset computing device when a user is remote according to an embodiment of the present invention.

### DESCRIPTION OF ILLUSTRATIVE EMBODIMENTS

Embodiments of the present invention can provide circuits, methods, and apparatus that can control the operation of components of headset computing devices and other types of devices. An illustrative embodiment of the present invention can provide a fan controller that can control a fan in a headset computing device. For example, when the headset computing device is removed by a user, the fan can be turned off. When the headset computing device is being worn by the user, the fan can be turned on as needed. For example, when a temperature of the headset computing device exceeds a first temperature threshold, the fan can turn on, otherwise the fan can be off.

The operation of various types of controllers can be determined by embodiments of the present invention. For example, a state of a controller that determines whether a fan is on or off can be determined. This fan controller can further determine a speed of the fan. The fan controller can further control one, two, or more than two fans of a headset computing device.

The state of a controller can depend on a change in whether the headset computing device is being worn. That is, the act of putting on or removing the headset computing device can change a state of the controller. The state of a controller can also be changed following events that occur while the headset computing device is being worn, or following events that occur while the headset is not being worn.

As an example, a headset computing device can determine that it has been or is being attached, for example, by being put on by a user. The fan controller of the headset computing device can then enter a state where the fan can turn on when needed. These and other embodiments of the present invention can further detect that the headset computing device has been detached, for example, by being removed by a user. The fan controller of the headset computing device can then enter a state where the fan stays off.

The fan controller can turn on or turn off the fan following various events while the headset computing device is being worn. For example, when the headset computing device is being worn, the fan controller can be in a state where the fan can turn on when needed. The fan controller can determine that a temperature above a first temperature threshold is being sensed in or on the headset computing device. In response, the fan controller can then turn the fan on. Once the temperature drops below the first temperature threshold, the fan controller can turn off the fan.

To prevent the fan from cycling on and off, hysteresis of various types can be utilized. For example, once the first temperature threshold is exceeded and the fan controller turns on the fan, the fan can remain on until the first sensed temperature is below a second temperature threshold, which can be an amount below the first temperature threshold. The hysteresis provided by the temperature difference between the first threshold and the second threshold can help to prevent short, repetitive cycling of the fan. In these and other embodiments of the present invention, once a fan turns on, the fan can be kept running by the controller for a period of time after the temperature falls below the first temperature threshold. The hysteresis provided by the period of time can help to prevent short, repetitive cycling of the fan.

In these and other embodiments of the present invention, more than one temperature threshold can be used to control the operation of the fan. For example, when the headset computing device is being worn, the fan controller can be in a state where the fan can turn on when needed. The fan controller can determine that a temperature above a first temperature threshold is being sensed in or on the headset computing device. In response, the fan controller can then turn the fan on. Additionally, one or more processes running on the headset computing device can be stopped or slowed. This can help to further speed the cooling of the headset computing device. If the sensed temperature in or on the headset computing device is below the first temperature threshold but above a second temperature threshold, the fan controller can start the fan. Since the temperature of the headset computing device is below the first temperature threshold, the processes can continue to run. If the temperature of the headset computing device is below the second threshold, the fan controller does not need to start the fan and all the various processes can run. While two temperature thresholds are used in this example, three or more temperature thresholds can be used, with various levels of mitigating steps taken as each temperature threshold is exceeded.

In these and other embodiments of the present invention, a fan can run at multiple speeds and the fan controller can control the speed of the fan. In the above example, when the second temperature threshold is exceeded, the fan can be on at a low speed. As the higher, first temperature threshold is exceeded, the fan can be on at a higher speed. In these and other embodiments of the present invention, the fan controller can operate the fan at a higher speed when a power dissipation load from the running processes is high, and the fan controller can operate at a lower speed when the power dissipation load from the running processes is low. Similarly, in these and other embodiments of the present invention, one or more fan controllers can control two or more fans. Two fans can be on in place of one fan running at high speed in the above examples. A single fan can be used in place of one fan running at low speed in the above examples.

Again, these and other embodiments of the present invention can detect that a headset computing device has been detached, or is not attached, for example, by being removed by a user. The fan controller of the headset computing device can then enter a state where the fan stays off.

In these and other embodiments of the present invention, the fan controller can allow the fan to continue to run for a short time after the headset computing device has been removed. This can help to reduce the temperature of the headset computing device after use. Having the fan run a short time after removal of the headset computing device might not be unexpected to a user.

In these and other embodiments of the present invention, various processes can continue to run on the headset computing device after removal by a user. For example, after a detection of a removal of the headset computing device is made, the fan can be stopped, either immediately or after a first time. If the sensed temperature in or on the headset computing device is above a first temperature threshold, all processes can be stopped. This can prevent overheating of the headset computing device since the fan controller is in the state where the fan is off. If the sensed temperature in or on the headset computing device is below the first temperature threshold, some or all of the processes can continue. Again some or all of the processes can stop if the temperature then increases above the first temperature threshold.

In these and other embodiments of the present invention, more than one temperature threshold can be used to control the operation of the fan. As before, after a detection of a removal of the headset computing device is made, the fan can be stopped, either immediately or after a first time. It can be determined that a temperature above a first temperature threshold is being sensed in or on the headset computing device. In response, all processes can be stopped. This can help to further speed the cooling of the headset computing device. If the sensed temperature in or on the headset computing device is below the first temperature threshold but above a second temperature threshold, some or all of the processes can be stopped or slowed. If the temperature of the headset computing device is below the second temperature threshold, the various processes can continue to run. While two temperature thresholds are used in this example, three or more temperature thresholds can be used, with various levels of mitigating steps taken as each temperature threshold is exceeded.

In these and other embodiments of the present invention, after a headset computing device has been removed, the fan controller can keep the fan running under certain circumstances. For example, if a user is not proximate to the headset computing device, the fan controller can keep the fan running if a temperature of the headset computing device is above a first temperature threshold. If the user is proximate, or if the temperature of the headset computing device is below the first temperature threshold, then the fan can be stopped. The headset computing device can determine that the user is not proximate by determining a distance to an accessory device used by the user, such as a watch or phone.

These and other embodiments of the present invention can run various types of processes. These processes can include firmware and software updates, as well as other processes often run in the background. Various applications running on a headset computing device can also be included, or those can be handled separately from embodiments of the present invention. These processes can be slowed by reducing a clock rate to processors and other circuits that are executing the processes.

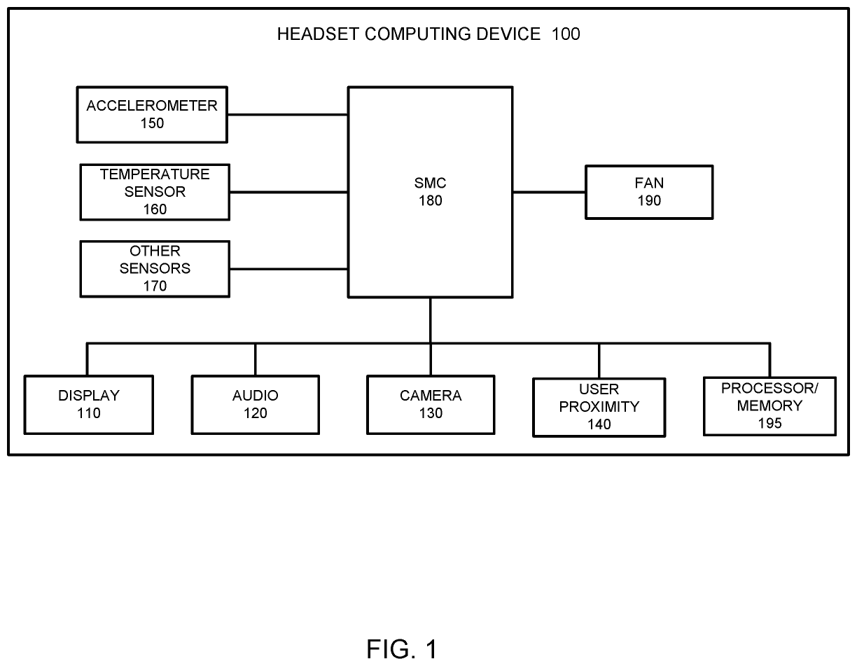

FIG. 1 is a block diagram of a headset computing device according to an embodiment of the present invention. This figure, as with the other included figures, is shown for illustrative purposes and does not limit either the embodiments of the present invention or the claims.

Headset computing device 100 can include one or more displays 110 for displaying images to a user. Audio circuits 120 can provide audio to the user through speakers (not shown) of the headset computing device 100. Audio circuits 120 can provide audio to the user wearing the headset computing device 100 via other accessories or devices, such as a phone, Bluetooth headset, speaker dock, or other audio player (not shown.) One or more cameras 130 can be included. These can take pictures, record video, provide real-time passthrough images, and perform other tasks as well. User proximity detector 140 can determine if a user is nearby. User proximity detector 140 can determine whether an accessory that might normally be worn or carried is nearby. For example, user proximity detector 140 can determine that a user's watch is being worn and is nearby. User proximity detector 140 can determine that a user's phone is being carried and is nearby. When such conditions occur, the headset computing device can determine that a user is nearby. In their absence, the headset computing device can determine that the user is not proximate. Headset computing device 100 can further include processor and memory 195. Processor and memory 195 can process and store data from the other components of headset computing device 100.

Headset computing device 100 can further include fan 190. Fan 190 can be controlled by system management controller 180. System management controller 180 can receive inputs from various sensors. For example, system management controller 180 can receive inputs from accelerometer 150, temperature sensor 160, as well as other sensors 170 of headset computing device 100. System management controller 180 can further receive inputs from display 110, audio circuit 120, camera 130, user proximity detector 140, and processor and memory 195.

In these and other embodiments of the present invention, system management controller 180 can run fan 190 when needed and can turn off fan 190 when its operation is undesirable. For example, when a user is not wearing headset computing device 100, system management controller 180 can turn fan 190 off. System management controller 180 can determine that a user is not wearing headset computing device 100 in various ways. For example, system management controller 180 can receive inputs from accelerometer 150 indicating that a user is moving headset computing device 100 in such a way as to indicate that headset computing device 100 is being removed. System management controller 180 can further received inputs from display 110, audio circuit 120, and camera 130 indicating that those circuits have turned off. System management controller 180 can determine that since those circuits have turned off, the user is no longer wearing headset computing device 100.

Fan 190 can be turned on when system management controller 180 determines that a user is wearing headset computing device 100 and that a temperature of headset computing device 100 is above a first threshold. System management controller 180 can determine that a user is wearing headset computing device 100 by receiving signals from accelerometer 150 indicating that a user is moving headset computing device 100 in such a way as to indicate that the user is putting on headset computing device 100. System management controller 180 can further received inputs from display 110, audio circuit 120, and camera 130 indicating that those circuits are turning on. System management controller 180 can determine that since those circuits are turning on, the user is now wearing headset computing device 100.

System management controller 180 can that a temperature of headset computing device 100 is above a threshold by receiving temperature data from temperature sensor 160. Temperature sensor 160 can be located in an interior of headset computing device 100. Temperature sensor 160 can be located at or near a surface of headset computing device 100. Headset computing device 100 can include multiple temperature sensors 160 positioned at various locations in or on headset computing device 100. Temperature sensor 160 can provide a signal indicating a temperature of headset computing device to system management controller 180. When temperature sensor 160 indicates to system management controller 180 that a temperature of headset computing device 100 is above a first threshold and the system management controller 180 has determined that a user is wearing headset computing device 100, system management controller 180 can turn on fan 190. When temperature sensor 160 indicates to system management controller 180 that a temperature of headset computing device 100 is below the first threshold, system management controller 180 can turn off fan 190.

In these and other embodiments of the present invention, a power management system daemon can control a fan controller in the system management controller. An example is shown in the following figure.

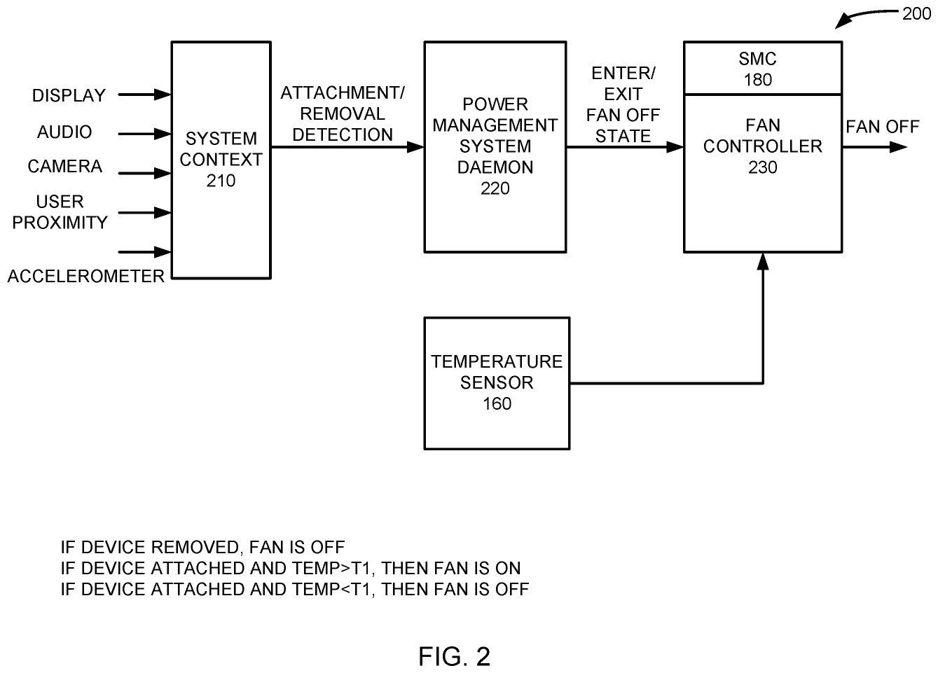

FIG. 2 is a block diagram of a system for controlling a fan according to an embodiment of the present invention. System context module 210 can receive inputs from a display, audio circuit, camera, user proximity detector, accelerometer, and other circuits (not shown.) System context module 210 can use the inputs to determine whether the headset computing device 100 (shown in FIG. 1) incorporating system 200 is being or has been attached (put on) or removed (taken off.)

For example, system context module 210 can receive inputs indicating that the display, audio circuits, or camera, are turning on. This can be used by system context module 210 to determine that headset computing device 100 is being attached. System context module 210 can receive input from accelerometer indicating that headset computing device 100 is being moved in such a way as to indicate it is being or has been attached.

System context module 210 can receive inputs indicating that the display, audio circuits, or camera, are turning off. This can be used by system context module 210 to determine that headset computing device 100 is being removed. System context module 210 can receive input from accelerometer indicating that headset computing device 100 is being moved (or is not being moved) in such a way as to indicate it is being or has been removed.

After system context module 210 determines that headset computing device 100 is being or has been attached or removed, power management system daemon 220 can instruct fan controller 230 to enter or exit the fan off state. For example, if headset computing device 100 is being or has been removed, power management system daemon 220 can instruct fan controller 230 to enter the fan off state. When fan controller 230 is in the fan off state, fan 190 (shown in FIG. 1) can be off. If headset computing device 100 is being or has been attached, power management system daemon 220 can instruct fan controller 230 to enter the fan on state. When fan controller 230 in the fan on state, fan 190 (shown in FIG. 1) can be turned on as necessary. Fan controller 230 can be a portion of or associated with system management controller 180.

When fan controller 230 is in the fan on state, fan controller 230 can turn on fan 190 when temperature sensor 160 indicates that a temperature of headset computing device 100 is above a threshold. When temperature sensor 160 indicates that a temperature of headset computing device 100 is below the threshold, fan controller 230 can turn fan 190 off. This method is shown following figure.

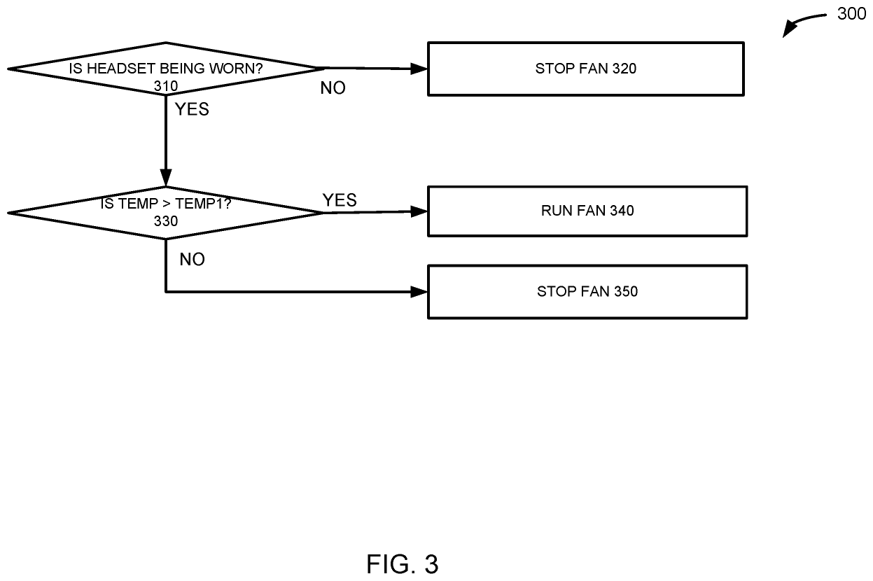

FIG. 3 illustrates a method of operating a fan of a headset computing device according to an embodiment of the present invention. In act 310 of method 300, it can be determined whether a headset computing device is being worn (is attached). If the headset computing device is not being worn (is removed), a fan of the headset computing device can be stopped in act 320. If the headset computing device is being worn, it can be determined in act 330 whether the temperature of headset computing device 100 is above a first threshold TEMP1. If the temperature of the headset computing device is above the first threshold TEMP1, the fan can be run in act 340. In act 350, if the temperature of headset computing device is below the first threshold TEMP1, the fan can be turned off or stopped.

The first threshold TEMP1 and the other thresholds employed by embodiments can be determined in various ways. For example, these thresholds can be programmable and updated as needed. They can be optimized and preloaded on to the headset computing device. They can have a set value, or they can have a value depending on various factors. These various factors can include the applications running on the headset computing device, the remaining battery power of the headset computing device, an expected length of time that the headset computing device might continue to be used, and other factors.

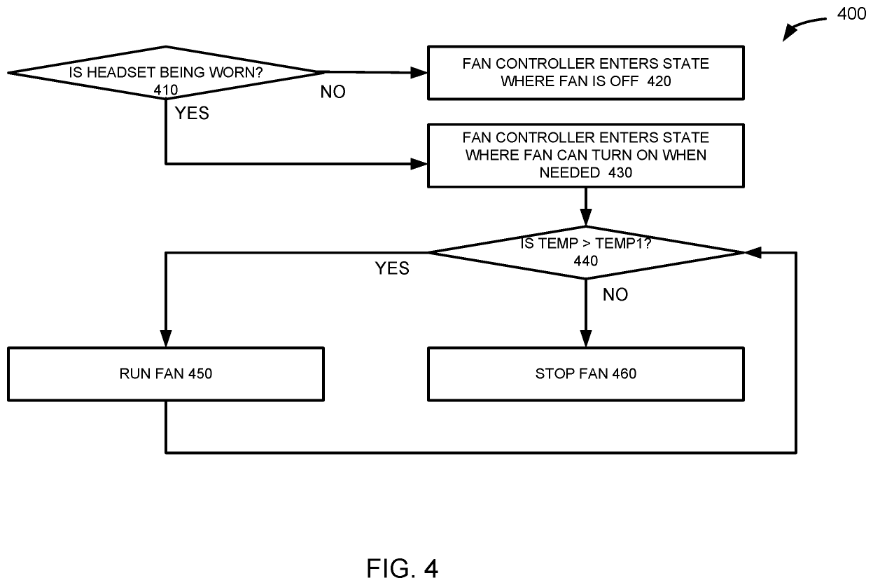

FIG. 4 illustrates another method of operating a fan of a headset computing device according to an embodiment of the present invention. In act 410 of method 400, it can be determined whether a headset computing device is being worn (is attached). If the headset computing device is not being worn (is removed), a fan controller of the headset computing device can enter a state where the fan is off in act 420. If the headset computing device is being worn, the fan controller can enter a state where the fan can turn on when needed in act 430. In act 440, it can be determined whether a temperature of headset computing device 100 is above a first threshold TEMP1. If the temperature of the headset computing device is above the first threshold TEMP1, the fan can be run in act 450. In act 460, if the temperature of headset computing device is below the first threshold TEMP1, the fan can be turned off or stopped.

In these and other embodiments of the present invention, it can be desirable to prevent fan 190 from repeatedly changing state (turning on and turning off) when the temperature of headset computing device 100 is approximately at first threshold TEMP1. Accordingly, embodiments of the present invention can include various types of hysteresis to prevent fan 190 from repeatedly changing state. Examples are shown in the following two figures.

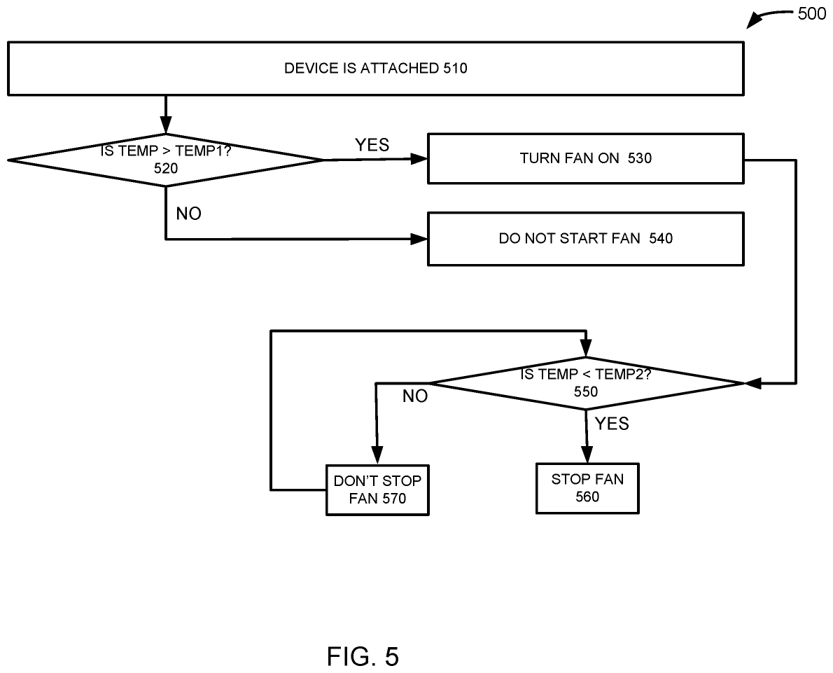

FIG. 5 illustrates another method of operating a fan of a headset computing device according to an embodiment of the present invention. In this example, a difference between two thresholds can be used to provide hysteresis in order to prevent fan 190 from repeatedly changing state.

In act 510 of method 500, a headset computing device can be attached. In act 520, it can be determined if a temperature of the headset computing device is above a first threshold TEMP1. If the temperature of the headset computing device is not above the first threshold TEMP1, the fan is not started in act 540. If the temperature of the headset computing device is above the first threshold TEMP1, then a fan can be turned on in act 530.

In act 550, it can be determined whether the temperature of the headset computing device is below a second threshold TEMP2, where the second threshold TEMP2 can be below the first threshold TEMP1. The temperature of the headset computing device is not below the second threshold TEMP2, the fan can continue to run in act 570, and the temperature of the headset computing device be checked again in act 550. If the temperature of the headset computing device is below the second threshold TEMP2, the fan can be stopped in act 560. In this way, once the fan is running, the temperature of the headset computing device can need to drop from the first threshold TEMP1 to the second threshold TEMP2 before the fan turns off. Similarly, once the fan turns off, the temperature of the headset computing device can need to rise from the second threshold TEMP2 to the first threshold TEMP1 before the fan turns back on.

Other types of hysteresis can be used in these and other embodiments of the present invention. For example, time can be used to provide hysteresis in controlling a fan of a headset computing device. An example is shown in the following figure.

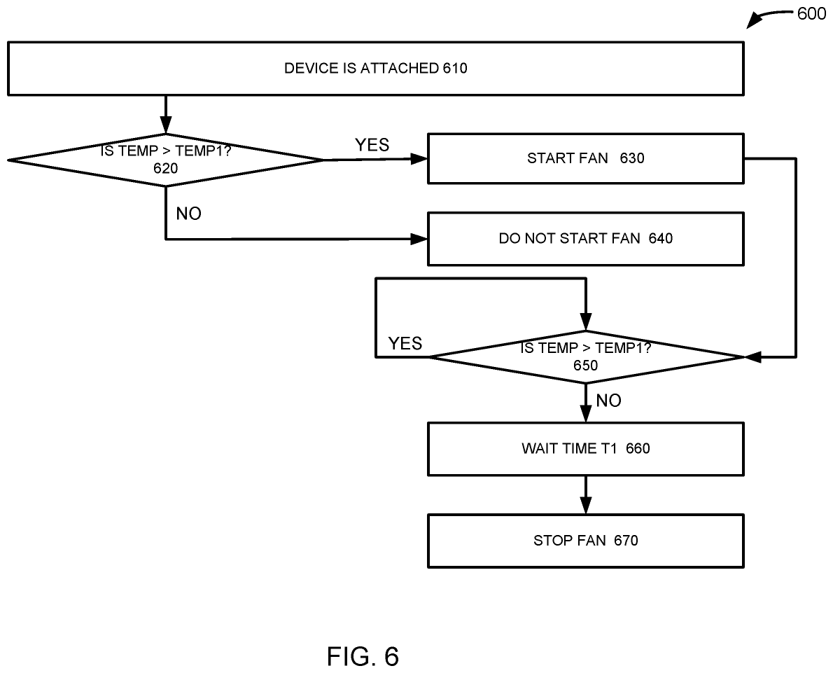

FIG. 6 illustrates another method of operating a fan of a headset computing device according to an embodiment of the present invention. In act 610 of method 600, a headset computing device can be attached. In act 620, it can be determined if a temperature of the headset computing device is above a first threshold TEMP1. If the temperature of the headset computing device is not above the first threshold TEMP1, the fan is not started (stopped) in act 640. If the temperature of the headset computing device is above the first threshold TEMP1, then the fan can be turned on in act 630.

In act 650, it can be determined whether the temperature of the headset computing device is greater than the first threshold TEMP1. If the temperature of the headset computing device remains above the first threshold TEMP1, the temperature can be rechecked at a later time. If the temperature of the headset computing device is below the first threshold TEMP1, the fan can continue to run for a time T1. After time T1, the fan can be stopped in act 670.

The time T1 employed by embodiments can be determined in various ways. For example, the time T1 can be programmable and updated as needed. T1 can be optimized and preloaded on to the headset computing device. T1 an have a set value, or it can have a value depending on various factors. These various factors can include the applications running on the headset computing device, the remaining battery power of the headset computing device, an expected length of time that the headset computing device might continue to be used, and other factors.

In these and other embodiments of the present invention, more than one temperature threshold can be used in determining an operation of a headset computing device. For example, a first temperature threshold can be used in determining whether to stop or slow one or more processes running on the headset computing device, while a second temperature threshold can be used in determining whether to stop or run the fan. In these and other embodiments of the present invention, three or more temperature thresholds can be used. An example is shown in the following figure.

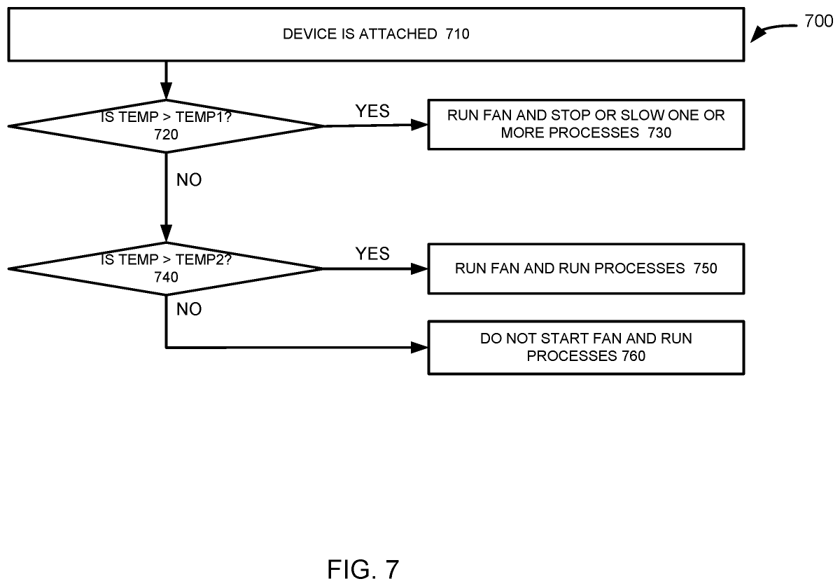

FIG. 7 illustrates a method of operating a fan of a headset computing device using more than one temperature threshold according to an embodiment of the present invention. In act 710 of method 700, it can be determined that a headset computing device has been attached. For example, it can be determined that the headset computing device is now being worn by a user. In act 720, it can be determined whether the temperature of the headset computing device is above a first threshold TEMP1. If the temperature of the headset computing device is above the first threshold TEMP1, then the fan can run and one or more processes running on the headset computing device can be stopped or slowed in act 730. In act 740, it can be determined whether the temperature of the headset computing device is above a second threshold TEMP2 but less than the first threshold TEMP1, where TEMP2 is less than TEMP1. If it is, the fan can run and the processes on the headset computing device can remain running. If the temperature of the headset computing device is less than TEMP2, the fan does not need to start and the processes can remain running.

These and other embodiments of the present invention can run various types of processes. These processes can include firmware and software updates, as well as other processes often run in the background. Various applications running on a headset computing device can also be included, or those can be handled separately from embodiments of the present invention. These processes can be slowed by reducing a clock rate to processors and other circuits that are executing the processes.

Again, in these and other embodiments of the present invention, more than one temperature threshold can be used in determining an operation of the headset computing device. Also, a headset computing device can include more than one fan. A first temperature threshold can be used in determining whether to run or stop a first fan, while a second temperature threshold can be used in determining to run or stop a second fan. In another example, one fan can run at a high speed and a low speed. A first temperature threshold can be used in determining whether to run the fan the low speed, while a second temperature threshold can be used to determine whether to run the fan at a high speed. An example is shown in the following figure.

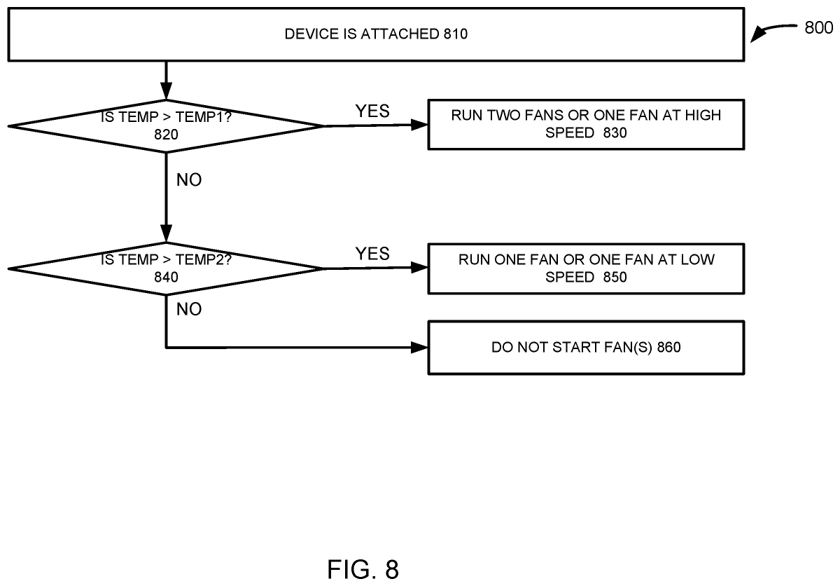

FIG. 8 illustrates a method of operating multiple fans of a headset computing device according to an embodiment of the present invention. In this example, a headset computing device can include two fans. In these and other embodiments of the present invention, the second fan can operate in tandem with the first fan as outlined in the various methods herein. In these and other embodiments of the present invention, the first fan and the second fan can be operated independently, and each fan can be started or stopped at their own temperature threshold.

In act 810 of method 800, a determination can be made whether the temperature is above a first threshold TEMP1. If the temperature of the headset computing device is above the first threshold TEMP1, two fans can run in act 830. In some examples, instead of two fans, one fan that can run at two different speeds can be used. In such an example, the one fan can run at a high speed in act 830. In act 840, it can be determined whether a temperature of the headset computing device is above a second threshold TEMP2 but below the first threshold TEMP1, where the second threshold TEMP2 is less than the first threshold TEMP1. If the temperature of the headset computing device is above a second threshold TEMP2 but below the first threshold TEMP1, then one fan can run in a headset computing device having two fans, or one fan can run at a low speed in a headset computing device having one fan of variable speed. When the temperature of the headset computing device is less than the second threshold TEMP2, all fans can be stopped.

In these and other embodiments of the present invention, it can be desirable to allow a fan to run for a period of time after a headset computing device has been removed. This can allow for cooling of the headset computing device after removal. An example is shown in the following figure.

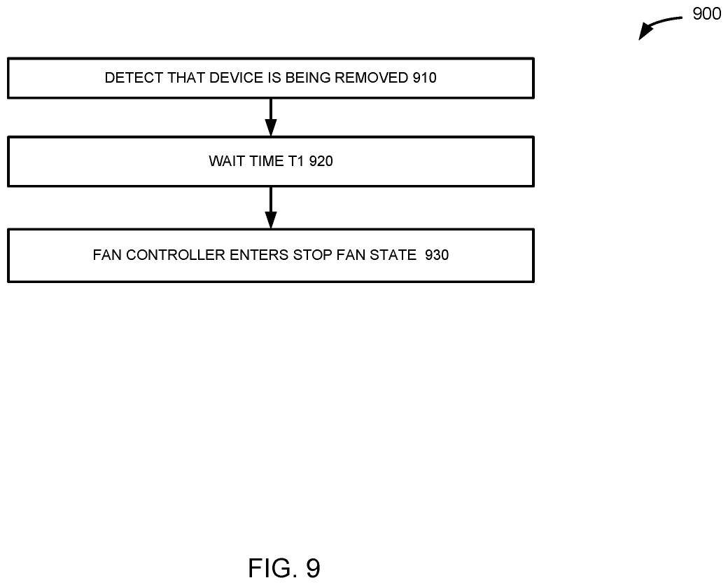

FIG. 9 illustrates another method of operating a fan of a headset computing device according to an embodiment of the present invention. In act 910 of method 900, a detection can be made that headset computing device is being removed. In act 920, a time T1 can be allowed to pass, and in act 930, the fan controller can enter the stop fan state. If the fan is not running when headset computing device is removed, the fan controller can enter the stop fan state and no change will be seen by the fan since it is already off. However, if the fan is running when the headset computing device is removed, the fan can be stopped when the fan controller enters the stop fan state.

In some circumstances, various processes can be running on a headset computing device when it is removed. In some situations, it can be desirable to complete these processes. These processes can include firmware updates, software updates, updates to the operating system, updates to various programs, and other types of updates. Depending on a temperature of headset computing device, these processes may need to be stopped or they may be allowed to continue. An example is shown in the following figure.

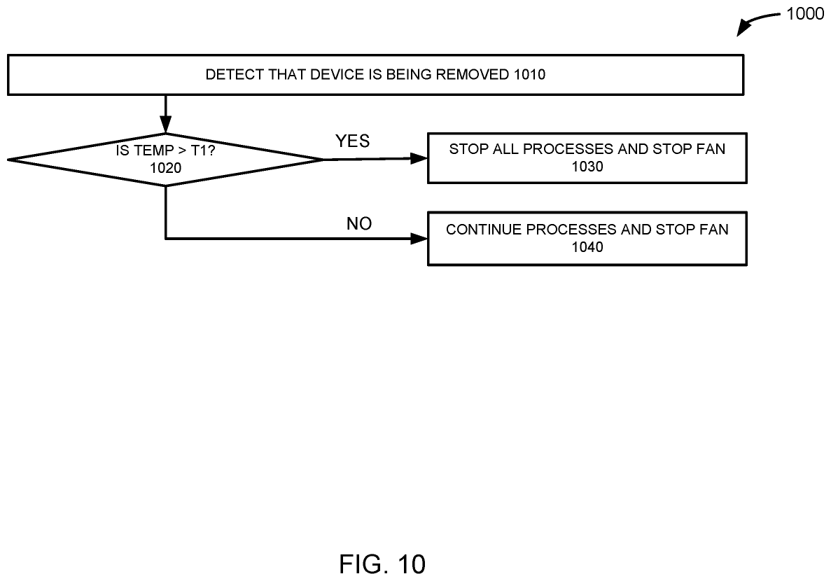

FIG. 10 illustrates another method of operating a fan of a headset computing device according to an embodiment of the present invention. In act 1010 of method 1000, it can be determined that a headset computing device has been or is being removed by a user. As shown above, when the headset computing device is being removed, it can be desirable to turn off the fan.

Accordingly, in act 1020, it can be determined whether a temperature of the headset computing device is above a first threshold TEMP1. If a temperature of the headset computing device is above the first threshold TEMP1, then all processes can be stopped and the fan can be stopped in act 1030. If a temperature of the headset computing device is below the first threshold TEMP1, the processes can continue while the fan is stopped in act 1040.

Again, in these and other embodiments of the present invention, more than one temperature threshold can be used. For example, when a headset computing device is removed, and a temperature of the headset computing device is above a first temperature, all processes can be stopped. If the temperature of the headset computing device is below the first temperature but above a second temperature, some of the processes can be stopped while others are allowed to run. If temperature of the headset computing device is below the second temperature, the processes can continue. In all of these circumstances, the fan can be stopped when headset computing device is removed. As shown above, the fan can be stopped immediately, or it can be allowed to run for a period of time before being stopped. An example is shown in the following figure.

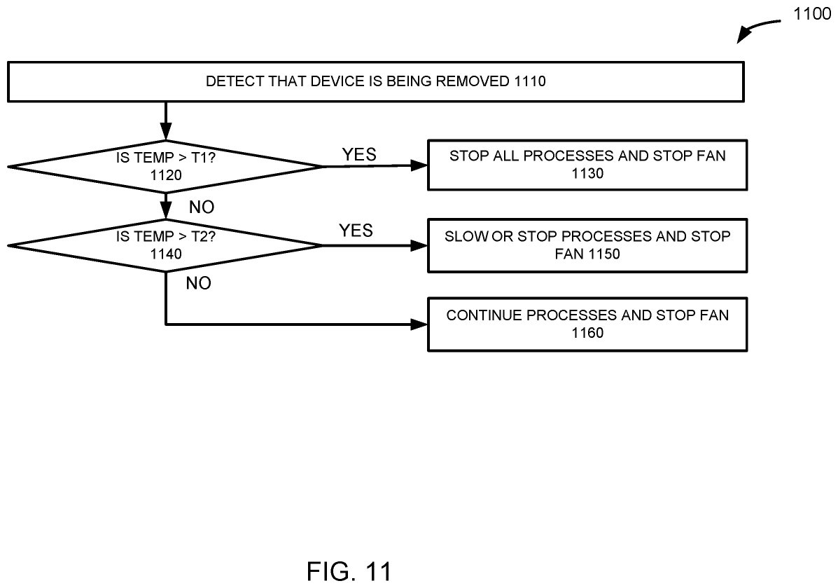

FIG. 11 illustrates a method of operating a fan of a headset computing device using more than one temperature threshold according to an embodiment of the present invention. In act 1110 of method 1100, a headset computing device can detect that it is being or has been removed. In act 1120, it can be determined whether a temperature of the headset computing device is greater than a first threshold TEMP1. If the temperature of the headset computing device is greater than the first threshold TEMP1, all processes and the fan can be stopped in act 1130. In act 1140, it can be determined whether a temperature of the headset computing device is greater than a second threshold TEMP2, where the second threshold TEMP2 is less than the first threshold TEMP1. If a temperature of the headset computing device is greater than the second threshold TEMP2, the various processes can be stopped or slowed and the fan can be stopped in act 1150. If a temperature of the headset computing device is less than the second threshold TEMP2, the processes can continue while the fan stopped in act 1160.

In these and other embodiments of the present invention, if a user is not proximate to a headset computing device that has recently been removed, the fan can remain running if needed. An example is shown in the following figure.

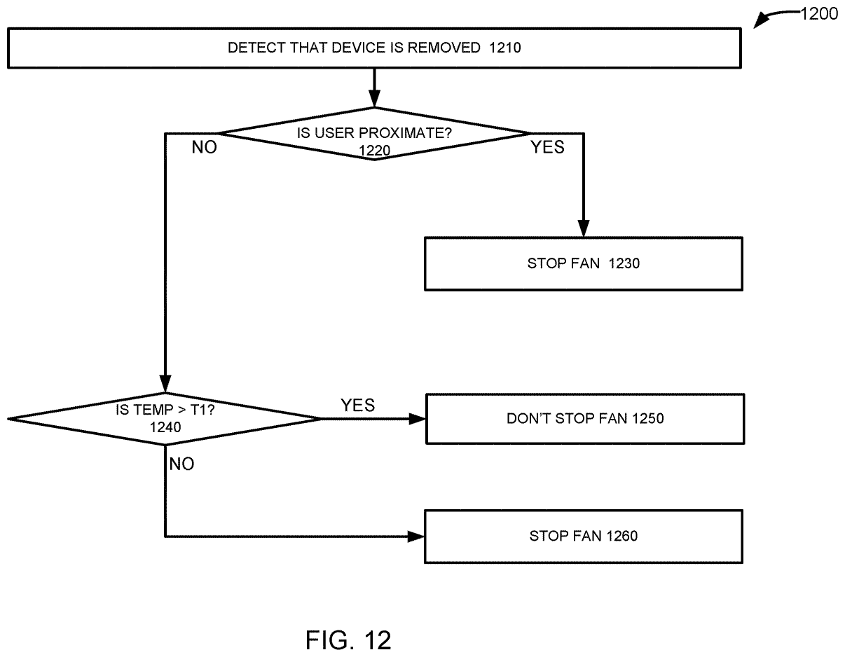

FIG. 12 illustrates a method of operating a fan of a headset computing device when a user is remote according to an embodiment of the present invention. In act 1210 of method 1200, a headset computing device can determine that it has been removed or detached. In act 1220, the headset computing device can determine whether a user is proximate. This determination can be made by determining whether an accessory that is typically or often carried or worn by the user is proximate. For example, the headset computing device can determine whether a watch that is typically worn by the user is proximate. The headset computing device can determine whether a phone that is typically carried by the user is proximate. If either of these is true, the headset computing device can determine that the user is proximate, otherwise the headset computing device can determine that the user is not proximate.

If the headset computing device determines that a user is proximate in act 1220, the fan can be stopped in act 1230. If the user is not proximate, then the headset computing device can determine whether its internal temperature is above a threshold TEMP1. If a temperature of the headset computing device is above the threshold TEMP1, the fan can continue to run (or not stopped) in act 1250. If a temperature of the headset computing device is below the first threshold TEMP1, the fan can be stopped in act 1260.

While embodiments of the present invention are well-suited to controlling fans in headset computing devices, embodiments of the present invention can control other circuits or components of headset computing devices, as well as other circuits or components of other types of electronic devices.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A headset computing device comprising:
a fan controller for controlling a fan of the headset computing device, wherein the fan controller is configured to:
stop the fan while the headset computing device is detached;
run the fan while the headset computing device is attached and a temperature of the headset computing device is above a first temperature threshold; and
stop the fan while the headset computing device is attached and the temperature of the headset computing device is below the first temperature threshold.

2. The headset computing device of claim 1 wherein when the headset computing device is detached, the fan controller enters a first state where the fan is off.

3. The headset computing device of claim 2 wherein when the headset computing device is attached, the fan controller enters a second state where the fan can be on if needed.

4. The headset computing device of claim 3 wherein when the headset computing device is attached when worn and the headset computing device is detached when not worn.

5. The headset computing device of claim 3 wherein the fan controller determines whether the headset computing device is attached or detached based on inputs from one or more of one or more components of the headset computing device including a display, an audio circuit, or a camera.

6. The headset computing device of claim 5 wherein the fan controller is further configured to:
determine that the headset computing device is attached;
determine that the headset computing device has become detached; and
run the fan for a first duration after determining that the headset computing device has become detached.

7. The headset computing device of claim 5 wherein the fan controller is further configured to:
determine that the headset computing device is attached;
determine that the temperature of the headset computing device is above a first temperature threshold and in response, to run the fan; and
determine that the temperature of the headset computing device is below the first temperature threshold and in response, wait a first duration and turn off the fan.

8. The headset computing device of claim 5 wherein the fan controller is further configured to:
determine that the headset computing device is attached;
determine that the temperature of the headset computing device is above a first temperature threshold and in response, to run the fan; and
determine that the temperature of the headset computing device is below the first temperature threshold and in response, turn off the fan.

9. A headset computing device comprising:
a system context module to receive inputs from components of the headset computing device to determine whether the headset computing device is attached or detached;
a power management system daemon to receive the determination of whether the headset computing device is attached or detached;
a temperature sensor to provide temperature information;
a fan;
a system management controller comprising a fan controller to control the fan, wherein:
when a determination is made that the headset computing device is detached, the power management system daemon instructs the fan controller to turn off the fan;
when a determination is made that the headset computing device is attached and the temperature information is that the headset computing device is above a first temperature threshold, the fan controller turns on the fan; and
when a determination is made that the headset computing device is attached and the temperature information is that the headset computing device is below the first temperature threshold, the fan controller turns off the fan.

10. The headset computing device of claim 9 wherein the inputs from the headset computing device comprise inputs from one or more components of the headset computing device including a display, an audio circuit, or a camera.

11. The headset computing device of claim 10 wherein when a determination is made that the headset computing device is detached, the power management system daemon instructs the fan controller to enter a state where the fan does not run.

12. The headset computing device of claim 10 wherein when a determination is made that the headset computing device is attached, the power management system daemon instructs the fan controller to enter a state where the fan can run when needed.

13. A headset computing device comprising:
a processor;
a display;
a camera;
an audio circuit;
a temperature sensor;
a system management controller comprising a fan controller; and
a fan controlled by the fan controller;
wherein the fan controller determines that the headset computing device is attached or detached based on inputs from one or more of the display, camera, or audio circuit, and:
when the headset computing device is detached, the fan controller enters a state where the fan is off;
when the headset computing device is attached, the fan controller enters a state where the fan can turn on;
when the headset computing device is attached and temperature sensor detects a temperature above a first temperature threshold, the fan controller runs the fan; and
when the headset computing device is attached and the temperature sensor detects a temperature below a second temperature threshold, the fan controller turns the fan off, wherein the second temperature threshold is equal to or less than the first temperature threshold.

14. The headset computing device of claim 13 wherein the fan controller is further configured to:
determine that the headset computing device is attached;
determine that the headset computing device has become detached; and
run the fan for a first duration after determining that the headset computing device has become detached.

15. The headset computing device of claim 13 wherein the fan controller is further configured to:
determine that the headset computing device is attached;
determine that the temperature of the headset computing device is above the first temperature threshold and in response, to run the fan; and
determine that the temperature of the headset computing device is below the first temperature threshold and in response, wait a first duration and turn off the fan.

16. The headset computing device of claim 13 wherein the second temperature threshold is less than the first temperature threshold, and the fan controller is further configured to:
determine that the headset computing device is attached;
determine that the temperature of the headset computing device is above the first temperature threshold and in response, to run the fan; and
determine that the temperature of the headset computing device is below the second temperature threshold and in response, turn off the fan.

17. The headset computing device of claim 13 further comprising a second fan, wherein the second temperature threshold is less than the first temperature threshold, and wherein when the temperature sensor detects a temperature above the first temperature threshold, the fan controller runs the fan and the second fan, and wherein when the temperature sensor detects a temperature below the first temperature threshold and above the second temperature threshold, the fan controller runs the fan and does not run the second fan.

18. The headset computing device of claim 17 wherein when the temperature sensor detects a temperature below the second temperature threshold, the fan controller does not run the fan and does not run the second fan.

19. The headset computing device of claim 13 wherein the second temperature threshold is less than the first temperature threshold, and when the temperature sensor detects a temperature above the first temperature threshold, the fan controller runs the fan at a high speed, and wherein when the temperature sensor detects a temperature below the first temperature threshold and above the second temperature threshold, the fan controller runs the fan at a low speed.

20. The headset computing device of claim 13 further comprising a proximity detect circuit, wherein when the proximity detect circuit detects that an accessory is not proximate to the headset computing device, the headset computing device has become detached, and the temperature sensor detects a temperature above the first temperature threshold, the fan controller runs the fan.
